(19) United States
(12) Patent Application Publication
(10) Pub. No.: US 2020/0057368 A1
(43) Pub. Date: Feb. 20, 2020

(54) PROCESS FOR IMPROVING THE CRITICAL DIMENSION UNIFORMITY OF ORDERED FILMS OF BLOCK COPOLYMERS

(71) Applicant: Arkema France, Colombes (FR)

(72) Inventors: Xavier Chevalier, Grenoble (FR); Raber Inoubli, Pau (FR); Christophe Navarro, Bayonne (FR); Celia Nicolet, Sauvagnon (FR)

(73) Assignee: Arkema France, Colombes (FR)

(21) Appl. No.: 16/656,103

(22) Filed: Oct. 17, 2019

Related U.S. Application Data
(63) Continuation of application No. 15/545,068, filed on Apr. 6, 2018, now abandoned.

(30) Foreign Application Priority Data
Jan. 21, 2015 (FR) 1550466

(51) Int. Cl. G03F 7/00; G03F 7/16; G03F 1/68; C09D 153/00; B05D 3/02; B05D 1/00; C08L 53/00

(52) U.S. Cl. CPC G03F 7/0002; G03F 7/168; G03F 7/162; G03F 1/68; C08L 2205/02; B05D 3/0254; B05D 1/005; C08L 53/00; C09D 153/00

(57) ABSTRACT

Provided is a process for controlling the critical dimension uniformity of ordered films of block copolymers on a nanometric scale. The invention also relates to the compositions used for controlling the critical dimension uniformity of ordered films of block copolymers and to the resulting ordered films that can be used in particular as masks in the lithography field.

### CROSS-REFERENCE TO RELATED APPLICATIONS

This patent application is a U.S. National Phase Patent Application of PCT Application No. PCT/FR2016/050113, filed Jan. 21, 2016, which claims priority to French Patent Application No. 1550466, filed Jan. 21, 2015, each of which is incorporated by reference herein in its entirety for all purposes.

### FIELD OF THE INVENTION

The present invention relates to a process for improving the critical dimension uniformity of ordered films of block copolymers on a nanometric scale. The invention also relates to the compositions used for improving the critical dimension uniformity of ordered films of block copolymers and to the resulting ordered films that can be used in particular as masks in the lithography field.

### BACKGROUND OF THE INVENTION

The use of block copolymers to generate lithography masks is now well known. While this technology is promising, difficulties remain in generating large surface areas of masks that can be industrially exploited. Processes for manufacturing masks for lithography which result in the best possible cylinder diameter regularity are in particular sought. This cylinder diameter regularity is characterized by the critical dimension uniformity.

The critical dimension uniformity (CDU) in an ordered film of block copolymers having a cylindrical morphology corresponds to the cylinder diameter size uniformity. In the ideal case, it is necessary for all the cylinders to have the same diameter, since any variation in this diameter will bring about variations in the performance levels (conductivity, characteristics of the transfer curves, thermal power discharged, resistance, etc.) for the applications under consideration.

Pure BCPs which organize themselves in ordered films and which have the best possible cylinder diameter regularity are difficult to obtain. Mixtures comprising at least one BCP are one solution to this problem, and it is shown in the present invention that, in the case where it is sought to obtain ordered films which have the best possible cylinder diameter regularity, mixtures comprising at least one BCP having an order-disorder temperature (TODT), combined with at least one compound not having a TODT, are a solution when the order-disorder transition temperature (TODT) of the mixture is lower than the TODT of the BCP alone. In this case, an improvement in the CDU is observed in comparison with an ordered film obtained with a block copolymer alone having a TODT for the same period.

The term “period” is understood to mean the minimum distance separating two neighboring domains having the same chemical composition, separated by a domain having a different chemical composition.

### SUMMARY OF THE INVENTION

The invention relates to a process which makes it possible to improve the critical dimension uniformity of an ordered film comprising a block copolymer, said ordered film comprising a mixture of at least one block copolymer having an order-disorder transition temperature (TODT) and at least one Tg with at least one compound not having a TODT, this mixture having a TODT below the TODT of the block copolymer alone, the process comprising the following steps:
mixing at least one block copolymer having a TODT and at least one compound not having a TODT, in a solvent,
depositing this mixture on a surface,
curing the mixture deposited on the surface at a temperature between the highest Tg of the block copolymer and the TODT of the mixture.

### BRIEF DESCRIPTION OF THE DRAWINGS

FIGS. 1 and 2 show the effect of various parameters used for image processing when determining the critical dimension uniformity of the cylinders;

FIG. 3 shows G′ and G″ moduli as a function of temperature for two copolymers; and

FIG. 4 shows SEM photos of a blended composition and a non blended copolymer for different thicknesses.

### DETAILED DESCRIPTION OF THE INVENTION

As regards the block copolymer(s) having an order-disorder transition temperature, any block copolymer, regardless of its associated morphology, may be used in the context of the invention, whether it is a diblock, linear or star triblock or linear, comb or star multiblock copolymer. Preferably, diblock or triblock copolymers and more preferably diblock copolymers are involved.

The order-disorder transition temperature TODT, which corresponds to a phase separation of the constituent blocks of the block copolymer, can be measured in various ways, such as DSC (differential scanning calorimetry), SAXS (small angle X-ray scattering), static birefringence, dynamic mechanical analysis, DMA, or any other method which makes it possible to visualize the temperature at which phase separation occurs (corresponding to the order-disorder transition). A combination of these techniques may also be used.

Mention may be made, in a non-limiting manner, of the following references referring to TODT measurement:
N. P. Balsara et al, Macromolecules 1992, 25, 3896-3901.
N. Sakamoto et al, Macromolecules 1997, 30, 5321-5330 and Macromolecule 1997, 30, 1621-1632
J. K. Kim et al, Macromolecules 1998, 31, 4045-4048.

The preferred method used in the present invention is DMA.

It will be possible, in the context of the invention, to mix n block copolymers with m compounds, n being an integer between 1 and 10, limits included. Preferably, n is between 1 and 5, limits included, and preferably n is between 1 and 2, limits included, and more preferably n is equal to 1, m being an integer between 1 and 10, limits included. Preferably, m is between 1 and 5, limits included, and preferably m is between 1 and 4, limits included, and more preferably m is equal to 1.

These block copolymers may be synthesized by any technique known to those skilled in the art, among which may be mentioned polycondensation, ring opening polymerization or anionic, cationic or radical polymerization, it being possible for these techniques to be controlled or uncontrolled, and optionally combined with one another. When the copolymers are prepared by radical polymerization, the latter can be controlled by any known technique, such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”).

According to one preferred form of the invention, the block copolymers are prepared by controlled radical polymerization, more particularly still by nitroxide mediated polymerization, the nitroxide being in particular N-(tert-butyl)-1-diethylphosphono-2,2-dimethylpropyl nitroxide.

According to a second preferred form of the invention, the block copolymers are prepared by anionic polymerization.

When the polymerization is carried out in radical fashion, the constituent monomers of the block copolymers will be chosen from the following monomers: at least one vinyl, vinylidene, diene, olefinic, allyl or (meth)acrylic monomer. This monomer is more particularly chosen from vinylaromatic monomers, such as styrene or substituted styrenes, in particular α-methylstyrene, silylated styrenes, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloylpropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, as well as fluoroolefinic monomers and vinylidene monomers, among which may be mentioned vinylidene fluoride, alone or as a mixture of at least two abovementioned monomers.

When the polymerization is carried out anionically, the monomers will be chosen, in a non-limiting manner, from the following monomers:

at least one vinyl, vinylidene, diene, olefinic, allyl or (meth)acrylic monomer. These monomers are more particularly chosen from vinylaromatic monomers, such as styrene or substituted styrenes, in particular α-methylstyrene, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloylpropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, as well as fluoroolefinic monomers and vinylidene monomers, among which may be mentioned vinylidene fluoride, alone or as a mixture of at least two abovementioned monomers.

Preferably, the block copolymers having an order-disorder transition temperature consist of a block copolymer, one of the blocks of which comprises a styrene monomer and the other block of which comprises a methacrylic monomer; more preferably, the block copolymers consist of a block copolymer, one of the blocks of which comprises styrene and the other block of which comprises methyl methacrylate.

The compounds not having an order-disorder transition temperature will be chosen from block copolymers, as defined above, but also random copolymers, homopolymers and gradient copolymers. According to one preferred variant, the compounds are homopolymers or random copolymers and have a monomer composition identical to that of one of the blocks of the block copolymer having a TODT.

According to a more preferred form, the homopolymers or random copolymers comprise styrene monomers or methacrylic monomers. According to a further preferred form, the homopolymers or random copolymers comprise styrene or methyl methacrylate.

The compounds not having an order-disorder transition temperature will also be chosen from plasticizers, among which mention may be made, in a non-limiting manner, of branched or linear phthalates, such as di-n-octyl, dibutyl, 2-ethylhexyl, diethylhexyl, diisononyl, diisodecyl, benzylbutyl, diethyl, dicyclohexyl, dimethyl, linear diundecyl and linear ditridecyl phthalates, chlorinated paraffins, branched or linear trimellitates, in particular diethylhexyl trimellitate, aliphatic esters or polymeric esters, epoxides, adipates, citrates and benzoates.

The compounds not having an order-disorder transition temperature will also be chosen from fillers, among which mention may be made of inorganic fillers, such as carbon black, carbon nanotubes or non-carbon nanotubes, fibres, which may or may not be milled, stabilizers (light stabilizers, in particular UV stabilizers, and heat stabilizers), dyes, and photosensitive inorganic or organic pigments, for instance porphyrins, photoinitiators, i.e. compounds capable of generating radicals under irradiation.

The compounds not having an order-disorder transition temperature will also be chosen from polymeric or non-polymeric ionic compounds.

A combination of the compounds mentioned may also be used in the context of the invention, such as a block copolymer not having a TODT and a random copolymer or homopolymer not having a TODT. It will be possible, for example, to mix a block copolymer having a TODT, a block copolymer not having a TODT and a filler, a homopolymer or a random copolymer for example not having a TODT.

The invention therefore also relates to the compositions comprising at least one block copolymer having a TODT and at least one compound, this or these compound(s) not having a TODT.

The TODT of the mixture which is the subject of the invention will have to be below the TODT of the organized block copolymer alone, but will have to be above the glass transition temperature, Tg, measured by DSC (differential scanning calorimetry), of the block having the highest Tg.

In terms of morphological behaviour of the mixture during self-assembly, this means that the composition comprising a block copolymer having an order-disorder transition temperature and at least one compound not having an order-disorder transition temperature will exhibit self-assembly at a temperature lower than that of the block copolymer alone.

The ordered films obtained in accordance with the invention exhibit an improved critical dimension uniformity compared with that obtained either with a single block copolymer having a TODT or with several block copolymers having a TODT for the same period.

The curing temperatures enabling self-assembly will be between the glass transition temperature, Tg, measured by DSC (differential scanning calorimetry), of the block having the highest Tg and the TODT of the mixture, preferably between 1 and 50° C. below the TODT of the mixture, preferably between 10 and 30° C. below the TODT of the mixture, and more preferably between 10 and 20° C. below the TODT of the mixture.

The process of the invention allows an ordered film to be deposited on a surface such as silicon, the silicon exhibiting a native or thermal oxide layer, germanium, platinum, tungsten, gold, titanium nitrides, graphenes, BARC (Bottom Anti-Reflective Coating) or any other anti-reflective layer used in lithography. Sometimes, it may be necessary to prepare the surface. Among the known possibilities, a random copolymer, the monomers of which may be totally or partly identical to those used in the composition of block copolymer and/or of the compound which it is desired to deposit, is deposited on the surface. In a pioneering article, Mansky et al. (Science, vol 275 pages 1458-1460, 1997) clearly describes this technology, which is now well known to those skilled in the art.

According to one variant of the invention, the surfaces can be said to be “free” (flat and homogeneous surface, both from a topographical and from a chemical viewpoint) or can exhibit structures for guidance of the block copolymer “pattern”, whether this guidance is of the chemical guidance type (known as “guidance by chemical epitaxy”) or physical/topographical guidance type (known as “guidance by graphoepitaxy”).

In order to manufacture the ordered film, a solution of the block copolymer composition is deposited on the surface and then the solvent is evaporated according to techniques known to those skilled in the art, such as, for example, the spin coating, doctor blade, knife system or slot die system technique, but any other technique can be used, such as dry deposition, that is to say deposition without involving a predissolution.

A heat treatment or treatment by solvent vapour, a combination of the two treatments, or any other treatment known to those skilled in the art which allows the block copolymer composition to become correctly organized while becoming nanostructured, and thus to establish the ordered film, is subsequently carried out. In the preferred context of the invention, the curing is carried out thermally at a temperature that is higher than TODT of block copolymer that exhibit a TODT.

The nanostructuring of a mixture of block copolymer having a TODT and of a compound deposited on a surface treated by means of the process of the invention resulting in the ordered film can take the forms such as cylindrical (hexagonal symmetry (primitive hexagonal lattice symmetry “6 mm”)) according to the Hermann-Mauguin notation, or tetragonal symmetry (primitive tetragonal lattice symmetry “4 mm”)), spherical (hexagonal symmetry (primitive hexagonal lattice symmetry “6 mm” or “6/mmm”)), or tetragonal symmetry (primitive tetragonal lattice symmetry “4 mm”), or cubic symmetry (lattice symmetry m % m)), lamellar or gyroidal. Preferably, the preferred form which the nanostructuring takes is of the hexagonal cylindrical type.

The critical dimension uniformity (CDU) in an ordered film of BCP corresponds to the cylinder diameter size uniformity. In the ideal case, it is necessary for all the cylinders to have the same diameter, since any variation in this diameter will bring about variations in the performance levels (conductivity, characteristics of the transfer curves, thermal power discharged, resistance, etc.) for the applications under consideration.

The images of the ordered films of BCP are taken on a CD-SEM H9300 from Hitachi. The CD measurements are determined from the SEM images with the imageJ software developed by the National Institutes of Health (http://imagej.nih.gov) following specific processing, although other image processing software can also be used to achieve the same result. The image processing is carried out in four different steps: 1/ “thresholding” of the image in order to delimit the circumference of the perpendicular cylinders (determination of the threshold of detection of the various levels of grey), 2/ determination of the area and diameter of the cylinders thus defined (they are likened to ellipsoids), 3/ distribution of the diameters of the cylinders in the image according to a Gaussian distribution, 4/extraction of the best parameters characterizing the Gaussian curve, including the specific “sigma” (standard deviation) thereof giving the value of the CDU.

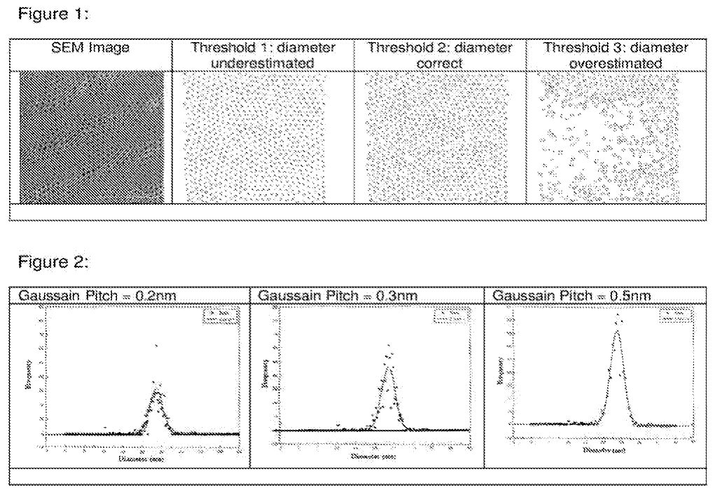

For a given image, the apparent diameter of the cylinders is strictly dependent on the image thresholding value: when the threshold is too low, the number of cylinders detected is correct and close to its maximum value, but their diameter is underestimated, and consequently the sigma of the Gaussian also. When the value of the threshold is correct, the correct number of cylinders is detected, and their diameter is close to its maximum value, without however it being certain that the apparent diameter is the correct one. Finally, when the value of the threshold is too high, the apparent diameter is very close to its maximum value, but by way of higher value (the value of the sigma is therefore possibly overestimated in this case), but a large number of cylinders is no longer detected since there is no longer any possible differentiation between the level of grey of the holes and the matrix. This effect of the value is illustrated in FIG. 1 (influence of the processing of the initial SEM image on the values of the diameter of the cylinders of the ordered film of BCP, initial image: 1349×1349 nm).

Moreover, for a given thresholding level, the best parameters for adjustment of the Gaussian curve depend on the “pitch” thereof: if the pitch is too small, some frequency values will be zero even if located in the middle of the cylinder diameter range. Conversely, if the pitch is too large, the adjustment according to a Gaussian curve no longer makes sense since all the values will have a single value. It is therefore necessary to determine the parameters for adjusting the Gaussian by various values of the curve pitch (FIG. 2, evolution of the characteristics (amplitude, position of the maximum, value of the sigma) of the Gaussian curve (solid line) adjusted with respect to the experimental values (dashed) for various pitch values).

In fact, a single image is processed according to three different threshold values, and the Gaussian curve obtained for each of these three values is itself processed according to three different pitch values. This therefore gives 9 CDU values for a given image, the real value of the CDU being located between the minimum and maximum values of the CDU range obtained.

### Example 1: Order-Desorder Transition Temperature Analysis by Dynamical Mechanical Analysis

Two different molecular weight block copolymers PS-b-PMMA are synthesized by conventially anionic process or commercially available product can be used. Characterizations of the products are in Table 1.

TABLE 1
Characterizations of PS-b-PMMA

| | Characterizations | | | | | |
|---|---|---|---|---|---|---|
| | Mp PS | Mp PMMA | Mp copo | | % m | % m |
| Product name | (kg/mol) | (kg/mol) | (kg/mol) | Dispersity | PS | PMMA |
| Copolymer 1 | 23.6 | 11.8 | 35.4 | 1.07 | 66.6 | 33.4 |
| Copolymer 2 | 63.2 | 29.0 | 92.2 | 1.09 | 68.5 | 31.5 |

These two polymers are analyzed in the same conditions by dynamical mechanical analysis (DMA). DMA enables the measure of the storage modulus G′ and loss modulus G″ of the material and to determine the phase tank defined as G″/G′.

Measurements are realized on an ARES viscoelastimeter, on which a 25 mm-PLAN geometry is set. The air gap is set at 100° C. and, once the sample settled in the geometry at 100° C., a normal force is applied to make sure of the contact between the sample and the geometry. A sweep in temperature is realized at 1 Hz. A 0.1% initial deformation is applied to the sample. It is then automatically adjusted to stay above the sensitivity limit of the probe (0.2 cm·g).

The temperature is set in step mode from 100 to 260° C., measurement is taken every 2° C. with an equilibration time of 30s.

For both polymers, some transitions are observed: after the glass transition (Tg) characterized by a first maximum of tank, the polymer reaches elastomeric plateau (G′ is higher than G″). In the case of a block copolymer that self-assembles, the block copolymer is structured on the elastomeric plateau.

After elastomeric plateau of Copolymer 1, G′ becomes lower than G″ which shows that the copolymer is not structured anymore. Order-disorder transition is reached and T_{odt} is defined as the first crossing between G′ and G″.

In the case of Copolymer 2, T_{odt} is not observed as G′ is always higher than G″. This block copolymer does not show any T_{odt} lower than its degradation temperature.

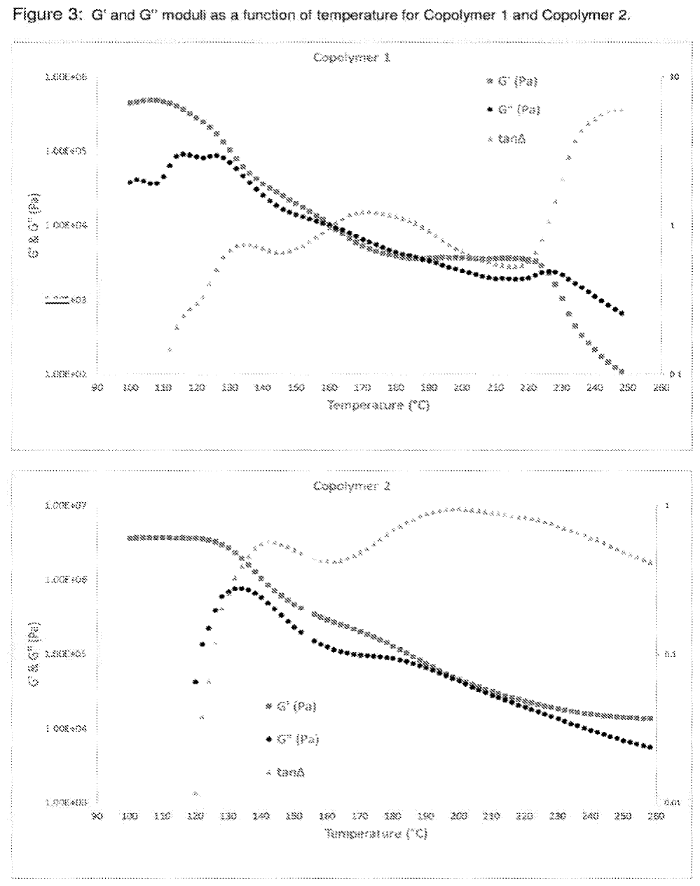

AMD results are in Table 2 and the associated graphs in FIG. 3.

TABLE 2
T_{odt} of different block copolymers PS-b-PMMA

| | T_{odt} |
|---|---|
| Copolymer 1 | 161 |
| Copolymer 2 | — |

### Example 2

Thicknesses and defectivity for direct self-assembly of block copolymers:

2.5×2.5 cm silicon substrate were used after appropriate cleaning according to known art as for example piranha solution then washed with distilled water.

Then a solution of a random PS-r-PMMA as described for example in WO2013083919 (2% in propylene glycol monomethylic ether acetate, PGMEA) or commercially available from Polymer source and as appropriate composition known from the art to be of appropriate energy for the block copolymer to be then self-assembled is deposit on the surface of the silicon substrate by spin coating. Other technic for this deposition can also be used. The targeted thickness of the film was 70 nm. Then annealing was carried out at 220° C. for 10 minutes in order to graft a monolayer of the copolymer on the surface.

Excess of non-grafted copolymer was removed by PGMEA rince.

Then a solution of bloc-copolymer (s) in solution (1% PGMEA) was deposit over the silicon treated substrate by spin coating to a obtained a targeted thickness. The film was then annealed for example at 230° C. for 5 min in so the bloc-copolymer(s) can self-assemble. Depending on the analysis to be performed (scanning electron microscopy, atomic force microscopy) contrast of the nanostructure could be enhanced by a treatment using acetic acid followed by distilled water rince, or soft oxygen plasma, or combination of both treatment.

Three different molecular weight block copolymers PS-b-PMMA were synthesized by conventially anionic process or commercially available product could be used. Characterizations of the products are in Table 2

| Block | Mp PS | Mp PMMA | Mp copo | | % m | % m | TODT | Period |
|---|---|---|---|---|---|---|---|---|
| copolymer | (kg/mol) ^{a} | (kg/mol) ^{a} | (kg/mol) ^{a} | Dispersity | PS ^{b} | PMMA ^{b} | (° C.) ^{c} | (nm) |
| Copolymer 3 | 59.9 | 26.4 | 86.3 | 1.11 | 69.4 | 30.6 | — | ~48 nm |
| Copolymer 4 | 67.4 | 31.1 | 98.5 | 1.18 | 68.4 | 31.6 | — | ~54 nm |
| Copolymer 5 | 23.6 | 10.6 | 34.2 | 1.09 | 69.0 | 31.0 | ~160 | ~24 nm |

^{a} As determined by SEC (sized exclusion chromatography, polystyren standards)
^{b} Détermined par NMR ¹H
^{c} Détermined par DMA (dynamical mechanical analysis as described in example 1). TODT for copolymer 3 and 4 does not exist.

Copolymers 4 and 5 were then blended (dry blending or solution blending) with a weight ratio of 80/20, ie 80% copolymer 4 and copolymer 3 was tested as comparative for the reference. Aim is to obtained the same period with blended copolymers 4 and 5 as for copolymer 3.

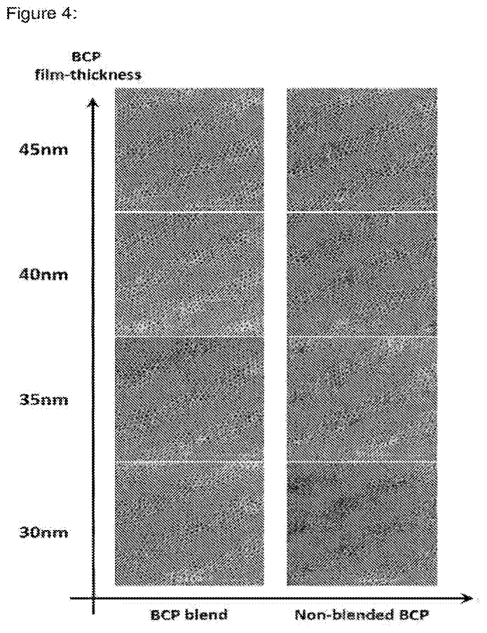

FIG. 4 exhibits SEM photos of blended composition (4 and 5) and non-blended copolymer 3 for different thicknesses.

It can be seen that blended composition exhibit more regular pattern.

SEM pictures were obtained using scanning electron microscope “CD-SEM H9300” from Hitachi with a magnifying of 100 000. Each picture as a dimension of 1349×1349 nm.

Numerical value on obtained with adequate known software were obtained and can be seen on table 3.

TABLE 3

| | Film | | Cylinders mean | Cylinder diameter |
|---|---|---|---|---|
| | thickness | Period | diameter | uniformity |
| | (nm) | (nm) | (nm) | (CDU; nm) |
| Copolymer 3 | 30 | 48.1 | 17.2 | 7.7 |
| | 35 | 48.1 | 18.5 | 7.4 |
| | 40 | 47.5 | 18.2 | 6.4 |
| | 45 | 46.6 | 18.0 | 6.4 |
| Blended | 30 | 48.4 | 18.2 | 2.7 |
| Copolymers 4 | 35 | 47.1 | 17.9 | 2.0 |
| and 5 | 40 | 47.3 | 17.4 | 1.9 |
| | 45 | 47.8 | 18.4 | 2.0 |

| | Film thickness | Period | Period uniformity |
|---|---|---|---|
| | (nm) | (nm) | (nm) |
| Copolymer 3 | 30 | 48.1 | 6.8 |
| | 35 | 48.1 | 5.9 |
| | 40 | 47.5 | 4.8 |
| | 45 | 46.6 | 4.2 |
| Blended Copolymers 4 | 30 | 48.4 | 2.9 |
| and 5 | 35 | 47.1 | 2.4 |
| | 40 | 47.3 | 2.4 |
| | 45 | 47.8 | 2.6 |

It is easily conclude that blended composition according to the invention exhibit the best results. Period uniformity and CDU is lower with blended composition according to the invention and therefore have a better homogeneity organisation.

1-22: (canceled)

23. A process for producing an ordered film, wherein the process comprises the following steps:
a) providing at least one first block copolymer, wherein the at least one first block copolymer has a first block copolymer order-disorder transition temperature (TODT) and at least one first block copolymer Tg;
b) providing at least one second block copolymer wherein the second block copolymer has at least one second block copolymer Tg and does not have a TODT;
c) mixing together in a solvent the at least one first block copolymer having a block copolymer TODT and the at least one second block copolymer not having a TODT, thereby producing a mixture, wherein the mixture has a mixture TODT that is below the first block copolymer TODT;
d) depositing the mixture on a surface; and
e) curing the mixture deposited on the surface at a curing temperature, wherein the curing temperature is between the highest Tg of the second block copolymer not having a TODT and the mixture TODT.

24. The process according to claim 23, wherein the first block copolymer having a TODT is a diblock copolymer.

25. The process according to claim 24, wherein one of the blocks of the diblock copolymer comprises a styrene monomer and the other block comprises a methacrylic monomer.

26. The process according to claim 25, wherein one of the blocks of the diblock copolymer comprises styrene and the other block comprises methyl methacrylate.

27. The process according to claim 22, wherein the second block copolymer not having a TODT is a diblock copolymer.

28. The process according to claim 27, wherein one of the blocks of the diblock copolymer comprises a styrene monomer and the other block comprises a methacrylic monomer.

29. The process according to claim 28, wherein one of the blocks of the diblock copolymer comprises styrene and the other block comprises methyl methacrylate.

30. The process according to claim 23, wherein the surface is free.

31. The process according to claim 23, wherein the surface is guided.

32. A composition comprising at least one first block copolymer having a TODT and at least one second block copolymer not having a TODT.

33. The process according to claim 23, wherein the process is used to produce lithography masks.

34. A lithography mask produced according to claim 33.

35. The process according to claim 23, wherein the process is used to produce ordered films.

36. An ordered film according to claim 35.
